(19) United States
(12) Patent Application Publication
(10) Pub. No.: US 2010/0045308 A1
(43) Pub. Date: Feb. 25, 2010

(54) METHOD FOR THE EARLY DETECTION OF DAMAGE TO A CAPACITIVE SENSOR, AND CAPACITIVE SENSOR FEATURING A DIAGNOSTIC FUNCTION

(76) Inventors: Juergen Hall, Rotenbach (DE); Markus Langenbacher, Schluchsee (DE); Ulrich Demisch, Freiburg (DE)

Correspondence Address: MUIRHEAD AND SATURNELLI, LLC, 200 FRIBERG PARKWAY, SUITE 1001, WESTBOROUGH, MA, 01581, US

(21) Appl. No.: 12/309,427

(22) PCT Filed: Jul. 21, 2006
(86) PCT No.: PCT/EP2006/007185

§ 371 Date: Oct. 2, 2009

(51) Int. Cl. G01N 27/22; G01R 27/26; G01N 21/00

(52) U.S. Cl. 324/658; 324/693; 356/237.1

(57) ABSTRACT

A system for the early detection of damage to and/or soiling of a capacitive sensor includes determining a degree by which the sensor is damaged and/or soiled by measuring a physical property of an electrode, e.g. the resistance of the electrode, or optically by means of the coefficient of reflection of the electrode surface of at least one electrode of the capacitive sensor. A capacitive sensor, according to the system described herein, may include components for provide the diagnostic function.

The present invention relates to a method for early detection of damage to a capacitive sensor and to a capacitive sensor which is designed for early detection and signaling of possible damage to the electrodes.

Capacitive sensors for determining dielectric properties of gases and liquids are widely being used in measurement and process technology. They are used in a plurality of industrial processes in which they are exposed to the effect of aggressive and corrosive substances. An incipient damage to the sensor, mostly a corrosion of the sensor electrodes, is initially not noticed by the user, and the damage often does not become apparent until total failure of the sensor occurs. The result is a shutdown of the process for several hours or longer until the defective device is replaced. Such a total failure often also means substantial financial loss, so that the user only has the option to frequently recalibrate the sensor and replace it preventively in regular intervals, which is also an unsatisfactory approach.

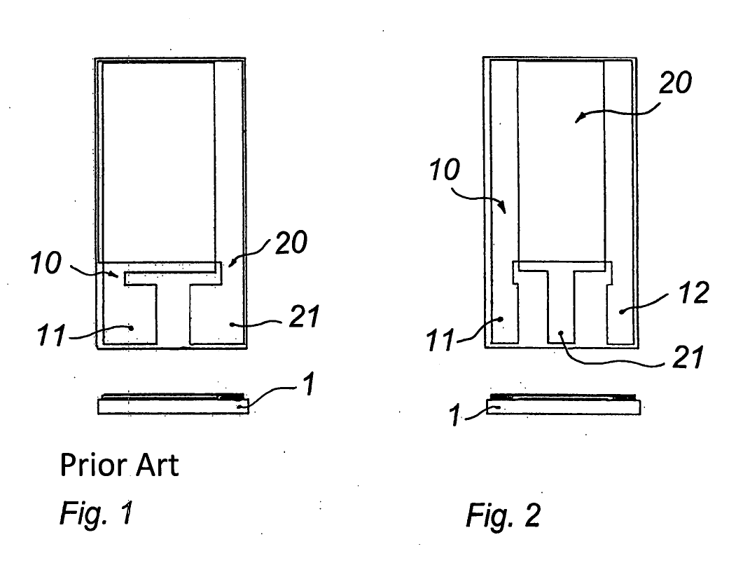

FIG. 1 shows a capacitive sensor according to the related art. A first electrode 10 having a terminal 11 is situated on a substrate 1. Above it, there is a second electrode 20 having a terminal 21 which is separated from first electrode 10 by a dielectric 30. A capacitance, which is a function of an electrical property of the dielectric or other parameters affecting the electrical properties of the dielectric, is measurable between first terminal 11 of first electrode 10 and terminal 21 of second electrode 20. If the sensor is exposed to aggressive substances which are continuously damaging the electrodes (10, 20), there is the risk of an unpredictable failure of the sensor with the above-described consequences.

The present invention is based on the object of providing a method for continuous monitoring of a capacitive sensor and for early detection of damage in capacitive sensors, as well as a sensor specially suited therefor.

This object is achieved by a method as recited in Patent Claim 1 and a capacitive sensor as recited in Patent Claim 13. Advantageous embodiments and refinements are the subject matter of the subclaims.

The present invention is based on the recognition that the extent of the damage to a capacitive sensor is directly derived from a physical property or a physical parameter of a sensor electrode. Such a physical property may be, for example, an electrical property such as the ohmic resistance of a sensor electrode, but also an optical property such as the reflection coefficient of the electrode surface.

Measuring these physical properties is easily possible without complicated adaptation of the sensor system proper. The method according to the present invention provides for measuring the physical property continuously or regularly in defined time intervals during the operation of the sensor. If the measured value differs excessively from a reference value (for example, the measured value for an undamaged sensor), a warning signal is output and the sensor should be replaced or recalibrated.

A typical capacitive sensor system includes a first electrode having a first terminal and a second electrode having a second terminal, the electrodes being separated by a dielectric. The capacitance of the sensor system is measured via the two terminals, from which in turn the desired electrical property of the dielectric or parameters affecting the electrical properties of the dielectric may be determined. Such a parameter may be, for example, the moisture content in the dielectric. The use in capacitive sensors for determining the quality of mineral oils or edible oils or liquid edible fats is also possible.

In one specific embodiment of the present invention, a second terminal is provided for the first electrode, so that in addition to the sensor capacitance between the two electrodes, the ohmic resistance of the first electrode between the first terminal and the second terminal may also be measured. With increasing damage to the sensor electrodes, the ohmic resistance of the first sensor electrode will also increase, so that, depending on the ohmic resistance, it may be decided whether a sensor is to be recalibrated or replaced before total failure occurs.

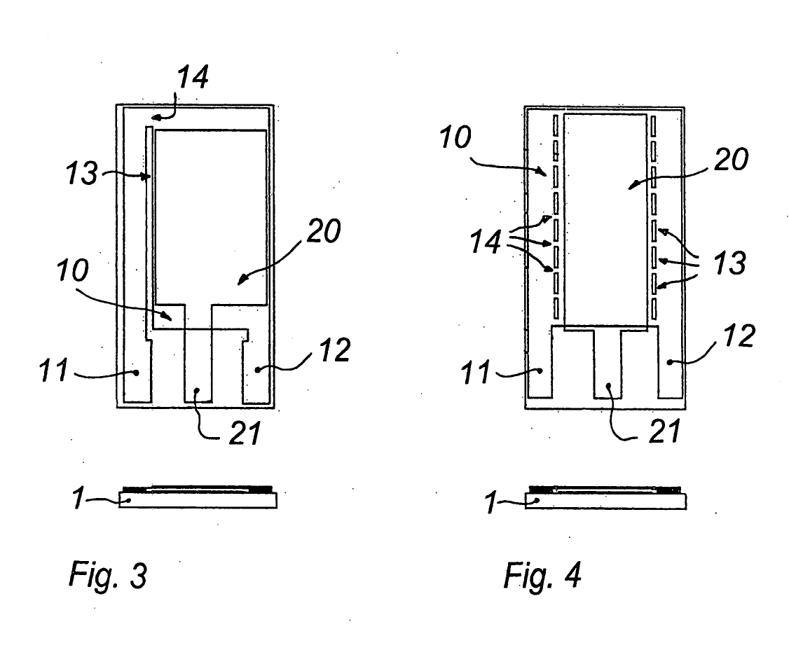

To magnify the effect of the increase in resistance with increasing damage to the sensor electrode, one or more slot-shaped recesses may be provided in the electrode between the first terminal and the other terminal of the first electrode, so that thin webs are formed between the slot-shaped recesses or between a slot-shaped recess and the edge of the electrode, which serve as predetermined breaking points. For example, if four thin webs through which a measuring current may flow are formed between the first terminal and the other terminal of the first electrode, and only one of these points breaks due to corrosion, the resistance of the overall system between the first terminal and the other terminal is increased by one-third. If three of the four webs break, the resistance will be four times that of the undamaged system. Furthermore, in the system illustrated in FIG. 3, the direction of the current flow is rotated essentially by 90° with respect to the system illustrated in FIG. 2, i.e., the current flows in the vertical direction, along the slot-shaped recess, which in turn increases the length of the current path and thus the total resistance. This results in advantages in analyzing the measuring signal (for example, higher signal levels, etc.).

The resistance of the first electrode may, however, also be measured in a contactless manner. In another specific embodiment of the present invention, a coil is situated in the immediate proximity of the first electrode, so that if an alternating signal is supplied to the coil, an eddy current is induced in the first electrode. The eddy current losses in the electrode and thus the impedance of the coil are clearly a function of the ohmic resistance of the first electrode, so that the ohmic resistance of the electrode and thus the damage to the capacitive sensor may also be inferred from the impedance of the coil.

In another, contactless specific embodiment, a third and a fourth electrode are situated in such a way that the third electrode and the first electrode, as well as the fourth electrode and the first electrode each form an auxiliary capacitor, so that a series circuit of a first auxiliary capacitor and an ohmic resistor and a second auxiliary capacitor is obtained, the ohmic resistor being formed, as previously, by the first electrode. The total impedance of this series circuit is also a function of the ohmic resistance of the first electrode; however, in addition, the capacitance values of the first and second auxiliary capacitors also change as a function of the damage to the sensor. Also in this case, the damage to the sensor may be inferred from the impedance of the series circuit, an additional effect, namely the change in the capacitance value of the auxiliary capacitors, contributing to the overall measured effect.

Another option for evaluating the damage to the sensor is by measuring an optical property such as, for example, the reflection coefficient of the first electrode. In such a specific embodiment, the first electrode of the capacitive sensor forms the reflector in a reflex optocoupler. A light source and a photodetector are situated in such a way that the light emitted by the light source is reflected on the surface of the first electrode prior to being received by the photodetector. In the event of increasing damage to the sensor, for example, by corrosion of the electrode, the reflection properties of the electrode are modified, so that the extent of the damage to the electrode may be determined from the intensity of the received light. Corrosion of the electrode affects both the scattering properties and the absorption properties of the electrode. The measuring effect is therefore such that, on the one hand, the absorption coefficient of the surface is modified and, on the other hand, the scattering properties are modified, so that the proportion of the light scattered toward the photodetector is modified. The intensity of the light received by the photodetector is a measure of the reflection coefficient of the electrode surface and thus a measure of the damage to the sensor. When the sensor is optically monitored, a mere soiling of the sensor electrodes may also be detected in addition to actual damage.

In a specific embodiment, light is injected into the dielectric between the two electrodes of the capacitive sensor via an optical fiber, so that the light is reflected multiple times back and forth between the two electrodes. The light reflected multiple times is extracted again via a second optical fiber and supplied to a photodetector. Also in this case, the intensity of the reflected light is a measure of the damage to the sensor. The principle is the same as described previously. The measuring effect is a modification in the absorption and scattering properties of the electrode surfaces.

The method according to the present invention allows a preferably continuous monitoring of the capacitive sensor by continuously measuring a suitable physical property (resistance, reflection coefficient, scattering properties, etc.) of an electrode. Of course, periodically or aperiodically repeated individual measurements are also possible. As soon as a measured value for the physical property exceeds a reference value, a warning signal, for example, may be triggered, whereupon the replacement of the corresponding sensor may be initiated. In addition, a prediction may be made from the variation of the measuring signal over time (for example, the variation of the measured electrode impedance) of how long the sensor may still be used under conditions that remain constant.

The present invention is elucidated below in greater detail with reference to exemplary embodiments illustrated in the figures.

FIG. 1 shows a capacitive sensor according to the related art, without a diagnostic function;

FIG. 2 shows a capacitive sensor having a first electrode and a second electrode, the first electrode having a first terminal and a second terminal, between which the ohmic resistance of the first electrode may be measured;

FIG. 3 shows a capacitive sensor such as in FIG. 2, in which additionally a slot-shaped recess is provided in the first electrode;

FIG. 4 shows a capacitive sensor such as in FIG. 2, in which a plurality of slot-shaped recesses is provided in the first electrode;

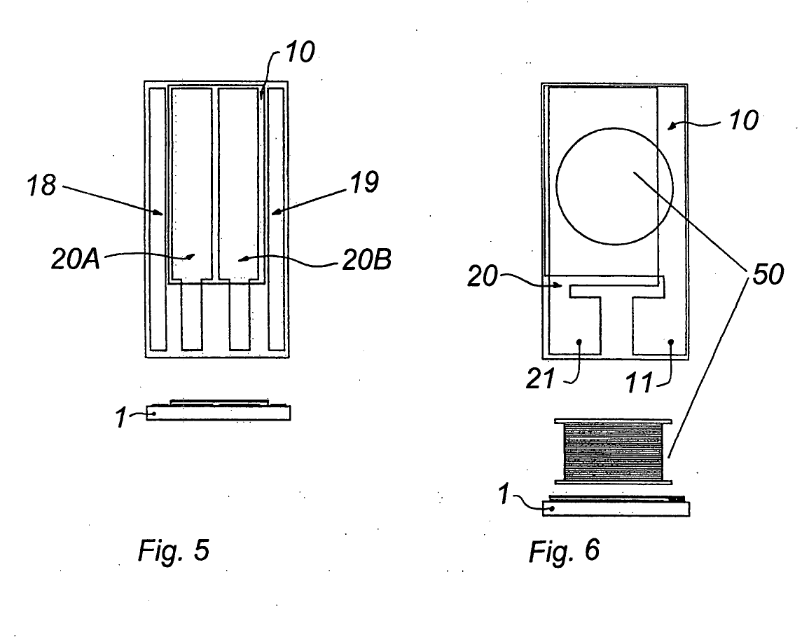

FIG. 5 shows a capacitive sensor having an additional third electrode and an additional fourth electrode, the third electrode, the first electrode, and the fourth electrode forming a series circuit of a first capacitor, an ohmic resistor, and a second capacitor;

FIG. 6 shows a capacitive sensor such as in FIG. 1, in which a coil is additionally provided for determining the ohmic resistance of the first electrode indirectly via the impedance of the coil;

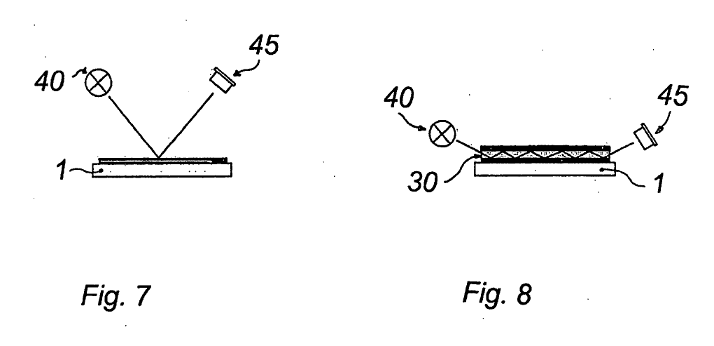

FIG. 7 shows a capacitive sensor in which the first electrode forms the reflector of a reflex optocoupler;

FIG. 8 shows a capacitive sensor in which the light is injected into the dielectric between the electrodes, where it is reflected multiple times;

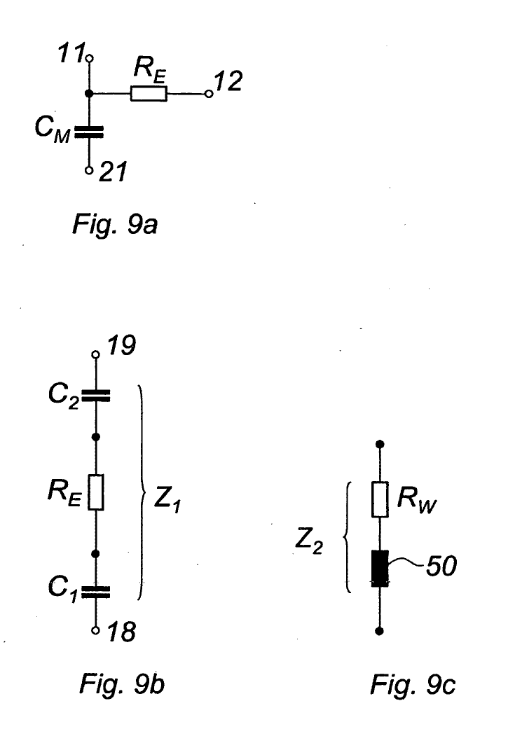

FIG. 9a shows the electrical equivalent circuit diagram for the sensor systems of FIGS. 2 through 4;

FIG. 9b shows the electrical equivalent circuit diagram for the sensor system of FIG. 5, and

FIG. 9c shows the electrical equivalent circuit diagram for the sensor system of FIG. 6.

In the figures, the same reference numerals identify the same elements.

FIG. 1 schematically shows a capacitive sensor without a diagnostic function according to the related art. As described in the introduction, this sensor system includes a first electrode 10 having a first terminal 11 and a second electrode 20 having a second terminal 21. Capacitance C_{M} is measurable between first terminal 11 of first electrode 10 and terminal 21 of second electrode 20.

FIG. 2 shows a capacitive sensor according to the present invention having a diagnostic function. The sensor includes a first electrode 10 having a first terminal 11 and a second terminal 12, and a second electrode 20 having a terminal 21. The desired capacitance C_{M} may be measured between first terminal 11 of first electrode 10 and terminal 21 of second electrode 20, as in the capacitive sensor according to the related art. Between its first terminal 11 and its second terminal 12, first electrode 10 represents an ohmic resistance R_{E}, which is measured for diagnostic purposes. This ohmic resistance R_{E} increases with increasing damage to first electrode 10. The measured value for R_{E} is therefore used for evaluating the extent of the damage to the sensor.

To magnify this effect, a slot-shaped recess 13 may be provided in the first electrode, so that a narrow web 14 is formed between first terminal 11 and second terminal 12 of first electrode 10. Such a system is shown in FIG. 3. Due to the narrow web, the current may flow basically only along slot-shaped recess 13, whereby a longer current path and thus a measured resistance R_{E} that is easier to evaluate is achieved compared to the system shown in FIG. 2.

In the specific embodiment shown in FIG. 4, a plurality of slot-shaped recesses 13 is situated between first terminal 11 and second terminal 12 of first electrode 10 next to each other along two parallel lines, so that a plurality of narrow webs 14 is created. These webs 14 are used almost as predetermined breaking points which break in the event of increasing corrosion of first electrode 10, whereby ohmic resistance R_{E} between first terminal 11 and second terminal 12 increases. This effect is considerably stronger than the increase in resistance in a system according to FIG. 2. The electrical equivalent circuit diagram of the specific embodiments shown in FIGS. 2 through 4 is illustrated in FIG. 9a.

In the specific embodiments illustrated in FIGS. 5 and 6 the electrode resistance is measured in a contactless manner. In the sensor illustrated in FIG. 5, a third electrode 18 and a fourth electrode 19 are situated in such a way that third electrode 18 and first electrode 10 form a first auxiliary capacitor C₁, and fourth electrode 19 and first electrode 10 form a second auxiliary capacitor C₂. First auxiliary capacitor C₁ and second auxiliary capacitor C₂ are connected in series via ohmic resistor R_{E} formed by first electrode 10. The electrical equivalent circuit diagram of this system is illustrated in FIG. 9b. In this specific embodiment of the present invention, impedance Z₁ of the series circuit is measured, which is clearly a function of ohmic resistance R_{E} of first electrode 10, but also of the capacitances of auxiliary capacitors C₁ and C₂. The extent of damage to the capacitive sensor may thus be inferred from the measured impedance Z₁. The measuring effect is not only a change in ohmic resistance R_{E}, but also a change in the capacitances of auxiliary capacitors C₁ and C₂ due to damage to the electrodes, whereby the overall effect is further enhanced.

In this specific embodiment, sensor capacitor C_{M} is formed by a series circuit of a first sensor capacitor C_{M1} and a second sensor capacitor C_{M2}. First sensor capacitor C_{M1} is formed by electrodes 20A and 10; second sensor capacitor C_{M2} is formed by electrodes 20B and 10. Due to the series circuit, the equation C_{M}=(C_{M1}·C_{M2})/(C_{M1}+C_{M2}) applies; the capacitance of the sensor capacitor is to be measured between the terminals of electrodes 20A and 20B. One advantage of this capacitive system is also that electrode 10 to be monitored does not need to have any electrical connection.

A second contactless system is shown in FIG. 6. A coil 50 is situated in the immediate proximity of first electrode 10 in such a way that if an alternating signal is supplied to the coil, an eddy current is induced in first electrode 10. On the one hand, impedance Z₂ of coil 50 is a function of the inductance of coil 50; on the other hand, it is a function of the eddy current losses which may be modeled in an equivalent circuit diagram (see FIG. 9c) as series resistance R_{W} to coil 50. This equivalent circuit diagram is shown in FIG. 9c. Series resistance R_{W} is clearly proportional to resistance R_{E} of first electrode 10. Also in this case, ohmic resistance R_{E} of first electrode 10 and thus the extent of the damage to the sensor may be inferred from impedance Z₂ of the coil. The electrical equivalent circuit diagram of this system is illustrated in FIG. 9c.

In another specific embodiment of the present invention, the reflection coefficient of first electrode 10 is used as a measure of the damage to the sensor. The surface of first electrode 10 is then used as a reflector in a reflex optocoupler. The system includes a light source 40 and a photodetector 45, the light emitted by light source 40 being reflected on the surface of first electrode 10 prior to being received by photodetector 45. The intensity of the light received by photodetector 45 is a measure of the reflection coefficient of first electrode 10 and is used as a measure of the damage to the capacitive sensor. Depending on the application, when the sensor is optically monitored, a mere soiling of the sensor electrodes may also be detected in addition to actual damage.

The exemplary embodiment illustrated in FIG. 8 is based on the same principle; in this embodiment the light of a light source 40 is injected into dielectric 30 between first electrode 10 and second electrode 20 via a first optical fiber in such a way that it is reflected multiple times back and forth between first electrode 10 and second electrode 20 prior to being extracted via a second optical fiber from the dielectric and supplied to a photodetector 45. The intensity of the light received by the photodetector is a measure of the reflection coefficient of the electrode surface and thus a measure of the damage to the capacitive sensor.

FIG. 9a shows the electrical equivalent circuit diagram for the specific embodiments of FIGS. 2 through 4. Sensor capacitor C_{M} formed by electrodes 10 and 20 and ohmic resistor R_{E} formed by first electrode 10 are shown. Resistor R_{E} is situated between terminals 11 and 12; sensor capacitor C_{M} is situated between terminals 11 and 21.

FIG. 9b shows the equivalent circuit diagram of the specific embodiment of FIG. 5. Impedance Z₁ of the system has a series circuit made up of first auxiliary capacitor C₁ formed by electrodes 18 and 10, resistor R_{E} formed by first electrode 10, and a second auxiliary capacitor formed by electrodes 10 and 19. The sensor capacitor itself is not illustrated in this figure.

FIG. 9C shows the equivalent circuit diagram of the specific embodiment of FIG. 6. The eddy current losses caused by coil 50 in first electrode 10 work as losses in an ohmic series resistor R_{W} in series with coil 50. Impedance Z₂ of the coil is thus formed by a series circuit made up by an inductor and series resistor R_{W}, series resistance R_{W} being proportional to resistance R_{E} of first electrode 10 in which eddy currents are induced.

A statistical analysis of the variation of the measuring signal over time (for example, the variation of the measured electrode impedance or of the measured reflected light intensity) allows a prediction to be made of how long the sensor may still be used under conditions that remain constant.

For this purpose, the original value of the corresponding physical parameter (i.e., electrode resistance, impedance, reflection coefficient, etc.) of the sensor must be measured at the end of the manufacturing process and saved in the sensor. During operation, the corresponding physical parameter is measured continuously or in certain time intervals and the measured values are saved together with a time stamp (i.e., together with the point in time of the measurement). From the saved measured values and the corresponding time stamps, a regression analysis is performed, i.e., a (for example, linear) trend is computed with the aid of a (for example, linear) regression function. Either polynomial functions or exponential functions may be used as regression functions. With the aid of the regression function, a point in time is extrapolated at which the corresponding physical parameter exceeds the critical threshold value which indicates unacceptably strong damage to the sensor. The user receives suitable information about the predictably necessary point in time of replacement of the sensor and may still plan a service date in a timely manner to prevent further damage.

1. A method for early detection of damage to a capacitive sensor comprising:
determining an extent of the damage to the capacitive sensor is by measuring a physical property of at least one electrode of the capacitive sensor.

2. The method as recited in claim 1, wherein the extent of the damage to the capacitive sensor is determined by measuring an ohmic resistance across the at least one electrode.

3. The method as recited in claim 2, wherein the ohmic resistance between a first terminal and a second terminal of the at least one electrode is measured.

4. The method as recited in claim 2, wherein an impedance of a coil situated in proximity of the at least one electrode, which is a function of the ohmic resistance of the at least one electrode, is measured.

5. The method as recited in claim 2, wherein an impedance of a series circuit formed by a first auxiliary capacitor, an ohmic resistor formed by the at least one electrode, and a second auxiliary capacitor, which is a function of the ohmic resistance of the at least one electrode, is measured.

6. The method as recited in claim 2, wherein an ohmic resistance of at least one electrode is compared to a certain reference value, and a comparison result is signaled by a certain logic level on a signal line.

7. The method as recited in claim 1, wherein a reflection coefficient of a surface of the at least one electrode is measured and a measurement result is used for evaluating the damage to the capacitive sensor.

8. The method as recited in claim 7, wherein the surface of the at least one electrode is used as a reflector of a reflex optocoupler.

9. The method as recited in claim 7, wherein light is injected into a dielectric which is adjacent to the at least one electrode via a first optic fiber, so that the light may propagate in the dielectric, and the light is supplied from the dielectric to a photodetector via a second optic fiber, the light being reflected at least once on the surface of the at least one electrode on the path from the first optical fiber to the second optical fiber through the dielectric.

10. The method as recited in claim 9, wherein an intensity of the reflected light is used for evaluating the damage to the capacitive sensor.

11. The method as recited in claim 1, wherein the physical property is measured continuously and a warning signal is triggered as soon as a measured value for the physical property exceeds a reference value.

12. The method as recited in claim 1, wherein the physical property is measured regularly in certain time intervals and a variation over time of measured values is analyzed for predicting a life expectancy of the capacitive sensor.

13. A capacitive sensor, comprising:
a first electrode;
a second electrode;
a dielectric that separates the first electrode and the second electrode, and
a physical property measuring device that measures a physical property of at least one of the electrodes.

14. The capacitive sensor as recited in claim 13, further comprising:
a resistance measuring device that measures an ohmic resistance of the first electrode.

15. The capacitive sensor as recited in claim 14, wherein the first electrode has a first terminal and a second terminal and the resistance measuring device measures the ohmic resistance of the first electrode between the two terminals.

16. The capacitive sensor as recited in claim 14, further comprising:
a coil situated in proximity of the first electrode, the coil inducing eddy currents in the first electrode which are a function of the ohmic resistance of the first electrode.

17. The capacitive sensor as recited in claim 14, further comprising:
a third electrode and a fourth electrode,
wherein the third electrode and the first electrode form a first auxiliary capacitor,
wherein the fourth electrode and the first electrode form a second auxiliary capacitor, and
wherein a resistor formed by the first electrode, the first auxiliary capacitor, and the second auxiliary capacitor form a series circuit.

18. The capacitive sensor as recited in claim 14, wherein an elongated slot-shaped recess is provided in the first electrode.

19. The capacitive sensor as recited in claim 14, wherein a plurality of linearly arranged recesses are provided in the first electrode.

20. The capacitive sensor as recited in claim 13, further comprising:
a light source and a photodetector, the light source, the photodetector, and the first electrode forming a reflex optocoupler which is used as a reflector for the first electrode.

21. The capacitive sensor as recited in claim 13, further comprising:
a light source and a photodetector,
wherein the photodetector is connected to the dielectric adjacent to the first electrode via a second optical fiber,
wherein the light source is connected to the dielectric via a first optical fiber, and
wherein light supplied to the dielectric through the first optical fiber is reflected multiple times on a surface of the first electrode prior to entering the second optical fiber.

22. The method according to claim 1, wherein the extent of damage to the capacitive sensor includes an extent of soiling of the capacitive sensor.
